(19) United States
(12) Patent Application Publication
(10) Pub. No.: US 2009/0100306 A1
(43) Pub. Date: Apr. 16, 2009

(54) ELECTRONIC UNIT

(75) Inventors: Yoshiaki Sugimura, Yokkaichi-City (JP); Tsuyoshi Hosono, Yokkaichi-City (JP)

Correspondence Address: CASELLA & HESPOS, 274 MADISON AVENUE, NEW YORK, NY, 10016, US

(73) Assignee: Sumitomo Wiring Systems, Ltd., Yokkaichi-City (JP)

(21) Appl. No.: 12/245,835

(22) Filed: Oct. 6, 2008

(30) Foreign Application Priority Data
Oct. 10, 2007 (JP) 2007-264530

(51) Int. Cl. G01R 31/28

(52) U.S. Cl. 714/734; 714/E11.17

(57) ABSTRACT

An MC 10 includes a universal asynchronous receiver transceiver UART as a communication circuit. A tester (6) includes a serial communication interface (61). By serial communication between these two, the operation of an electronic unit 1 is tested. A common output circuit (31) is provided as an output circuit of the UART 11. This common output circuit (31) is a circuit which doubles as one of output circuits of the MC 10, one end thereof is connected to a UART port and another general port of the MC 10 and the other end thereof is connected to a terminal connected to a load (7).

### BACKGROUND OF THE INVENTION

1. Field of the Invention

The invention relates to an electronic unit incorporating a microcomputer and particularly to a vehicle-mounted electronic unit.

2. Description of the Related Art

An electronic unit to be mounted in an automotive vehicle or the like includes a microcomputer (hereinafter, “MC”), input circuits for inputting operation signals from external switches to the MC and output circuits for outputting drive signals corresponding to the operation signals to loads. The electronic unit may be connected with a tester, for example, to perform a shipment test. The tester generates input logics of the switches and gives the inputs logics to the input circuits to determine whether the MC and the output circuits operate properly.

Some electronic units include an external communication interface, such as a vehicle LAN. In this case, the tester can use the communication interface to conduct and efficient test through serial communication. However, many electronic units do not include a vehicle LAN or the like, and there is a desire to enable an efficient test for such electronic units without increasing cost.

U.S. Pat. No. 6,226,574 discloses the use of a general output port and an output circuit of a MC as a communication interface circuit with a tester. However, software is necessary for communication processing when the general output port of the MC is used as the communication interface. As a result, the program size and cost are increased.

Japanese Unexamined Patent Publication No. 2002-168915 discloses a method for testing an electronic unit by using a MC with a UART (Universal Asynchronous Receiver Transceiver). The method includes providing a circuit board incorporating the MC with a pad wired to a UART port and bringing a probe of a tester into contact with the pad. According to this method, no software is necessary for communication processing. However, the pad is not exposed to the outside if the circuit board is in a case and hence it may be impossible to bring the probe into contact with the pad.

The invention was developed in view of the above problems and an object thereof is to provide an electronic unit efficiently testable without increasing cost and, particularly to an electronic unit including no external communication interface such as a vehicle LAN and testable even after a circuit board incorporating a MC is cased, as well as an improved testing method.

### SUMMARY OF THE INVENTION

The invention relates to an electronic unit with a microcomputer that has ports for signal input/output, terminals electrically connected with the ports of the microcomputer, and output circuits provided between the ports and the terminals. The microcomputer includes a communication circuit and a testing port connected with the communication circuit. The output circuits include a common output circuit with one end connected to the testing port and another port of the microcomputer and another end connected to one of the terminals. The common output circuit functions as a communication interface with a tester to output a test response signal corresponding to an output signal from the testing port when the tester is connected with the other end thereof. However, the common output circuit functions as a driving circuit for driving a specified load device to output a drive signal corresponding to an output signal from the other port when the load device is connected with the other end thereof.

The communication circuit preferably is a universal asynchronous receiver transceiver.

The electronic unit preferably is a vehicle-mounted electronic unit to be mounted in a vehicle and to conduct no information communication with another electronic unit mounted in the vehicle.

In a testing mode of the common output circuit, the other port preferably is an input port, and preferably has a high impedance, so as not to hinder a communication output from the testing port.

Changes in the port settings preferably are made when a control signal indicating the start of a testing mode is fed from the tester to the microcomputer.

The tester preferably includes a communication interface, and most preferably a serial communication interface, for communication between the microcomputer and the tester.

The invention also relates to a testing method that comprises providing a microcomputer having ports for signal input/output. The microcomputer preferably includes a communication circuit and a testing port connected with the communication circuit. The method also includes providing terminals electrically connected with the ports of the microcomputer, and providing output circuits between the ports and the terminals. The output circuits include a common output circuit having one end connected to the testing port and another port of the microcomputer and having the other end connected to one of the terminals. The method then includes outputting a test response signal corresponding to an output signal from the testing port when a tester is connected with the other end of the common output circuit or driving a specified load device by means of the common output circuit to output a drive signal corresponding to an output signal from the other port when the load device is connected with the other end thereof.

The testing method preferably further comprises a step of using a universal asynchronous receiver transceiver as the communication circuit.

Preferably, the microcomputer is part of an electronic unit which is a vehicle-mounted electronic unit mounted in a vehicle, and wherein the electronic unit is used to conduct no information communication with another electronic unit mounted in the vehicle.

The port settings preferably are changed when a control signal indicating the start of a testing mode is fed from the tester to the microcomputer.

The microcomputer includes the communication circuit. Accordingly, no software for communication processing with the tester is necessary. The common output circuit has one end connected to the testing port and the other port of the microcomputer and has the other end connected to one of the terminals. In other words, the common output circuit doubles as the output circuit for the load device and the communication interface circuit with the tester. Thus, there is no need to provide a separate circuit for communication with the tester on a circuit board, and a mounting space taken up by components and cost can be reduced. Further, by using the terminal connected to the other end of the common output circuit, a test can be conducted even after the circuit board incorporating the microcomputer is in a case.

These and other objects, features and advantages of the present invention will become more apparent upon reading of the following detailed description of preferred embodiments and accompanying drawings. It should be understood that even though embodiments are separately described, single features thereof may be combined to additional embodiments.

### BRIEF DESCRIPTION OF THE DRAWINGS

FIG. 1 is a simplified block diagram showing a circuit construction at the time of a shipment test of an electronic unit 1 according to one embodiment of the invention.

FIG. 2 is a block diagram showing the electronic unit 1 shown in FIG. 1 in detail.

FIG. 3 is a circuit diagram showing a set state of output circuits connected to output ports of a MC.

FIG. 4 is a circuit diagram showing a state where a common output circuit is connected to output ports of the MC.

### DETAILED DESCRIPTION OF THE PREFERRED EMBODIMENTS

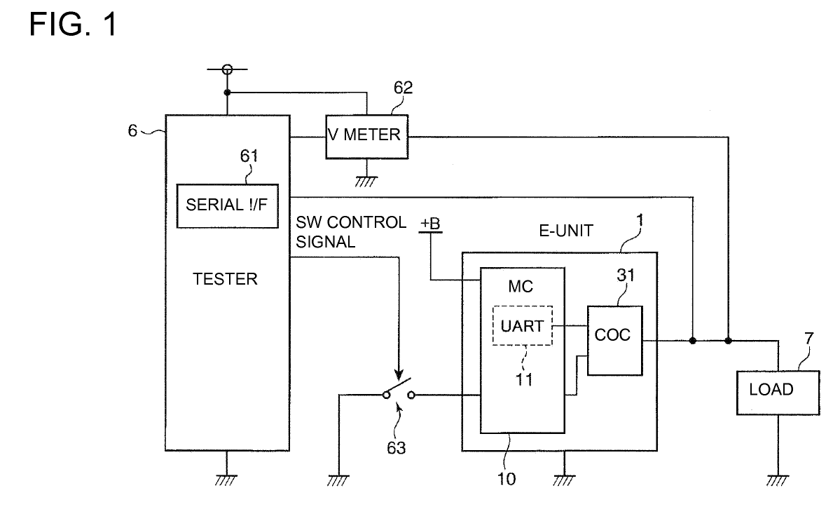

FIG. 1 is a simplified block diagram showing a circuit construction at the time of a test (such as a shipment test) of an electronic unit 1 according to one embodiment of the invention. The electronic unit 1 is installed at proper positions of various automotive vehicles, such as passenger or commercial vehicles for controlling various functions of the vehicles, e.g. various electrical components called a body system.

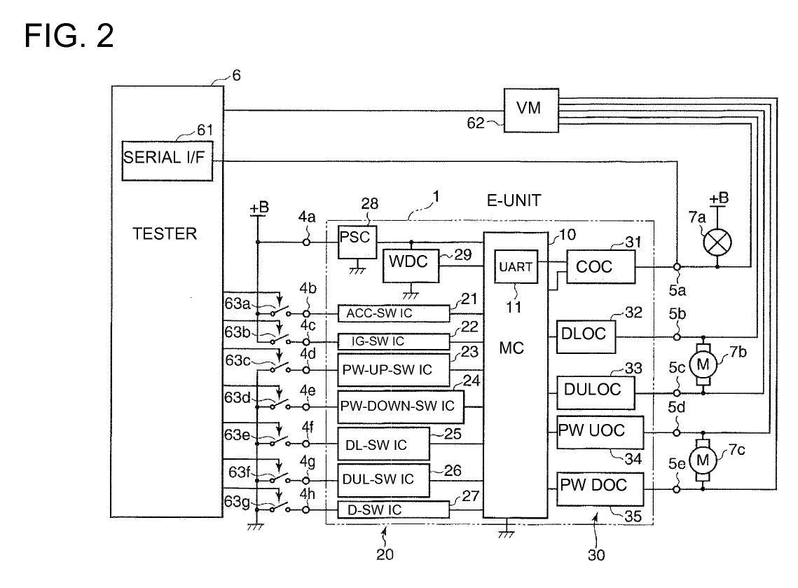

The electronic unit 1 is provided with a microcomputer (MC) 10 including a read-only memory (ROM) storing one or more control programs relating to this body system control, a random access memory (RAM) for temporarily saving or storing various data, a CPU (central processing unit) for reading the control programs from the ROM and implementing them, etc. and adapted to govern the body system control. As shown in detail in FIG. 2, input circuits and output circuits including a common output circuit 31 are connected to the MC 10 and are accommodated in a case while being mounted on a board. Terminals are connected electrically with ports of the MC 10 accommodated in the case via the input or output circuits and are at least partly exposed on the case.

A voltage meter 62 and a switch 63 are to be connected with the electronic unit 1 to test an electrical operating state of the electronic unit 1 at the time of a shipment test. The switch 63 is connected to a terminal at an input circuit side of the electronic unit 1, and the voltage meter 62 is connected to a terminal at an output circuit side of the electronic unit 1, to which a load 7 is connected. Normally, a switch control signal is generated in the tester 6 to control the switch 63, and a specified input logic is generated and given to the input circuits for the test of the electronic unit 1. Thus, the voltage meter 62 may detect whether the MC 10 and the output circuits operate properly, i.e. whether the electronic unit 1 outputs a proper drive signal to the load 7 in accordance with the switch control signal.

The MC 10 additionally includes a universal asynchronous receiver transceiver (hereinafter, “UART 11”) as a communication circuit. Further, the tester 6 includes a serial communication interface 61. Serial communication between these two enables the operation of the electronic unit 1 to be tested even without turning the switch 63 on and off. Further, the common output circuit 31 is provided as an input/output circuit of the UART 11.

The common output circuit 31 doubles as one of the output circuits of the MC 10. One end of the common output circuit 31 is connected to a UART testing port and another general port of the MC 10, and the other end thereof is connected to one of the terminals. The common output circuit 31 functions as a communication interface with the tester 6 to output a test response signal corresponding to an output signal from the testing port e.g. when a probe of the tester 6 is connected with the terminal in a testing mode. On the other hand, in a mode for driving the load 7, the common output circuit 31 functions as a load driving circuit and outputs a drive signal corresponding to an output signal from the general port. A specific circuit construction example of the common output circuit 31 is described in detail below.

FIG. 2 is a block diagram showing the electronic unit 1 shown in FIG. 1 in detail. The electronic unit 1 has the above MC 10, input circuits 20 and output circuits 30 with first ends connected to specified ports of the MC 10, input terminals 4a to 4h connected to the second ends of the input circuits 20, and output terminals 5a to 5e connected to the other ends of the output circuits 30. The electronic unit 1 is a vehicle-mounted electronic unit to be mounted in a vehicle such as an automotive vehicle, and conducts no vehicle network or LAN communication with other vehicle-mounted electronic units mounted in the vehicle. Thus, this electronic unit 1 includes no communication interface circuit for vehicle network or LAN.

In this example, the input circuits 20 include an ACC switch (ACC-SW) input circuit 21, an ignition switch (IG-SW) input circuit 22, a power window up-switch (UP-SW) input circuit 23, a power window down-switch (DOWN-SW) input circuit 24, a door lock switch (door unlock SW) input circuit 25, a door unlock switch (door unlock-SW) input circuit 26 and a door switch (door-SW) input circuit 27. These input circuits 21 to 27 are connected respectively to switches 63a to 63g via the input terminals 4b to 4h.

In this example, the output circuits 30 include the above common output circuit 31, a door lock output circuit 32, a door unlock output circuit 33, a power window up output circuit 34 and a power window down output circuit 35. The common output circuit 31 drives a load device (e.g. a dome lamp 7a) and also functions as a communication interface circuit with the tester 6. The door lock output circuit 32 and the door unlock output circuit 33 drive a door lock motor 7b. The power window up output circuit 34 and the power window down output circuit 35 drive a power window motor 7c. These output circuits 31 to 35 are connected to the dome lamp 7a, the door lock motor 7b and the power window motor 7c via output terminals 5a to 5e provided outside the case covering the electronic unit 1.

The electronic unit 1 further is provided with a power supply circuit 28 and a watchdog circuit 29 for checking a power supply level and suppressing a runaway of the MC. The power supply circuit 28 is connected to a power source (such as an unillustrated battery) via the input terminal 4a.

During normal use of the electronic unit 1, signals outputted from the input circuits 21 to 27 are inputted to the MC 10. Upon receiving these input signals, the MC 10 controls the common output circuit 31 for driving the respective device such as the dome lamp 7a, the door lock output circuit 32, the door unlock output circuit 33, the power window UP output circuit 34 and the power window DOWN output circuit 35 to drive the dome lamp 7a, the door lock motor 7b and/or the power window motor 7c.

On the other hand, at the time of a test of the electronic unit 1, e.g. in the case of testing the power window up-switch input circuit 23 and the power window up output circuit 34, the switch 4d of the power window up-switch input circuit 23 is turned on with the switch 4c of the ignition switch input circuit 22 turned on to check whether a drive signal is given to the power window motor 7c. Thus, the normality of a “power window up” function of the electronic unit 1 can be tested. Tests for the other circuits may be conducted similarly.

The above tests can be conducted by successively turning the switches 63a to 63g of the input circuits 20 on and off in the tester 6, converting voltages outputted from the output circuits 30 into digital signals in the voltage meter 62 and feeding these digital signals back to the tester 6. These tests can be conducted efficiently by serial communication between the serial communication interface 61 of the tester 6 and the UART 11 of the MC 10. In other words, the tests can be conducted by transmitting serial data on the tests from the tester 6 to the electronic unit 1, returning corresponding data from the electronic unit 1 to the tester 6, and judging the precision of the return data.

For example, tests as shown in (1) to (3) below can be illustrated as test contents.

### (1) Test for the Operations of the Input Circuits 20

On and off switch signals are fed successively to the input terminals 4b to 4h of the electronic unit 1 by the operations of the switches 63a to 63g of the tester 6. The states of the input ports of the MC 10 at this time are read by the tester 6 through the serial communication between the serial communication interface 61 and the UART 11 and it is checked whether the signals fed to the input terminals 4b to 4h of the electronic unit 1 have been transmitted correctly to the input ports of the MC 10 via the input circuits 20.

(2) Test for the Operations of the MC 10 and/or the Output Circuits 30

Serial data for instructing the output ports of the MC 10 to give high and low outputs are transmitted from the tester 6 to the MC 10. The states of the output ports of the MC 10 corresponding to the instruction serial data are read by the tester 6 through the serial communication between the serial communication interface 61 and the UART 11 and/or voltages outputted from the output terminals 5a to 5e via the output circuits 30 are read by the tester 6 via the voltage meter 62 to check whether the output contents conform to the instructed contents.

### (3) Reading/Writing Test

The MC 10 is instructed from the tester 6 to read/write in/from the RAM (not shown) included in the electronic unit 1 through serial communication between the serial communication interface 61 and the UART 11, and it is checked whether these are correctly performed.

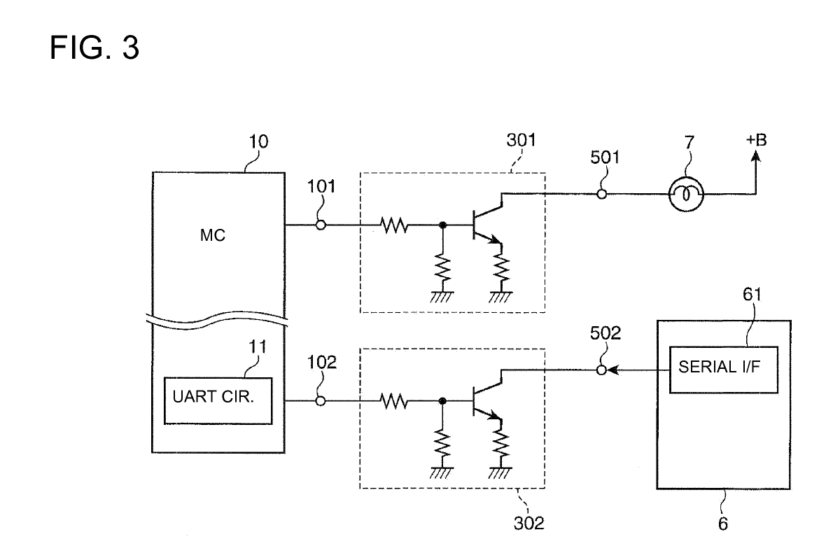

As described above, the electronic unit 1 of this embodiment is a unit including no communication interface circuit for vehicle LAN. Thus, it is necessary to set an output circuit for the UART 11 in addition to the load driving output circuits. FIG. 3 is a circuit diagram showing a set state of such output circuits. An output circuit 301 for driving a load 7 is provided between a general output port 101 of the MC 10 and an output terminal 501 connected to the load 7. Further, a communication output circuit 302 is provided between a UART port 102 for the UART 11 and an output terminal 502 connected to the serial communication interface 61 of the tester 6.

In the case of the circuit construction shown in FIG. 3, circuit components of the communication output circuit 302 have to be mounted on a circuit board, on which the MC 10 is mounted, only for the communication with the tester 6 at the time of the test. This unnecessarily takes up a mounting space for circuit components and leads to a cost increase.

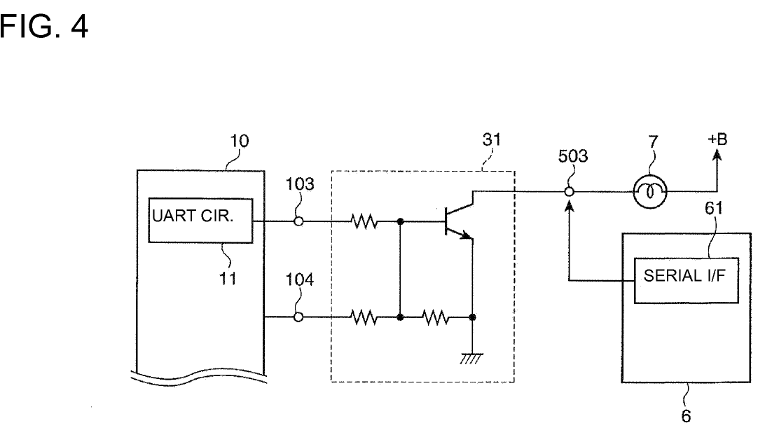

In view of such a problem, the common output circuit 31 is provided in this embodiment and doubles as the output circuit for serial communication with the tester 6 and the output circuit for driving the load. In other words, as shown in FIG. 4, the common output circuit 31 has one end connected to a UART testing port 103 of the MC 10 for the UART 11 and a general output port 104 and has the other end connected to one output terminal 503. The load 7 and the serial communication interface 61 of the tester 6 are connected to the output terminal 503.

Here, to obtain proper outputs of the common output circuit 31 both in a testing mode and in a load driving mode, the settings of the UART port 103 and the general output port 104 are changed in both modes. Specifically, as shown in TABLE-1 below, the UART port 103 is used as a communication port for test, i.e. as an output port in the testing mode. At this time, the general output port 104 is set as an input port (high impedance) so as not to hinder a communication output from the UART port 103. On the other hand, in the load driving mode, the general output port 104 is used, for example, as a load driving PWM port, i.e. as an output port. At this time, the UART port 103 is set as an input port (high impedance) so as not to hinder a communication output from the general output port 104. The changes in the port settings as described above may be made, for example, when a control signal indicating the start of the testing mode is fed from the tester 6 to the MC 10.

TABLE 1

| REFERENCE | | | LOAD |
|---|---|---|---|
| NUMERAL | PORT NAME | SHIPMENT TEST | DRIVING |
| 103 | COMMUNICATION | OUTPUT | INPUT |
| | PORT FOR | | |
| | SHIPMENT TEST | | |
| 104 | PWM PORT FOR | INPUT | OUTPUT |
| | LOAD DRIVING | | |

Since the same circuit doubles as the output circuit for serial communication and the output circuit for load driving in the case of the circuit construction shown in FIG. 4, it is not necessary to mount special circuit components for communication with the tester 6 on the circuit board, which is advantageous in light of the mounting space and/or cost. The circuit board incorporating the MC 10 is accommodated in the case, but it is normally sufficient to bring the probe or the like of the tester 6 into contact with the output terminal 503 exposed outside the case. Therefore, there is an advantage of being able to conduct specified tests even after the board incorporating the MC is accommodated in the case.

Accordingly, to provide an electronic unit efficiently testable without increasing cost, a microcomputer (MC) 10 includes a universal asynchronous receiver transceiver (UART) 11 as a communication circuit. A tester 6 includes a serial communication interface 61. The operation of an electronic unit 1 may be tested by serial communication between these two. A common output circuit 31 is provided as an output circuit of the UART 11. This common output circuit 31 doubles as one of output circuits of the MC 10, one end thereof is connected to a UART port and another general port of the MC 10 and the other end thereof is connected to a terminal connected to a load 7.

The invention is not limited to the above embodiment and can be embodied in various different ways. For example, in the above embodiment, the common output circuit 31 that doubles as the circuit for driving the dome lamp 7a and the circuit for serial communication with the tester 6 is illustrated. However, the common output circuit 31 may double as any one of the door lock output circuit 32, the door unlock output circuit 33, the power window up output circuit 34 and the power window down output circuit 35. Further, although the vehicle mounted electronic unit 1 is illustrated in the above embodiment, the present invention is also applicable to various other electronic units used without being mounted in vehicles.

What is claimed is:

1. An electronic unit (1), comprising:
a microcomputer (10) having a plurality of ports (103, 104; 102, 101) for signal input/output, a plurality of terminals (4a-4h, 5a-5e; 501, 502) electrically connected with the ports (103, 104; 102, 101) of the microcomputer (MC), and
output circuits (30, 31; 301, 302) provided between the ports (103, 104; 102, 101) and the terminals (4a-4h, 5a-5e; 501, 502),
wherein:
the microcomputer (10) includes a communication circuit (11) and a testing port (103) connected with the communication circuit (11),
the output circuits include a common output circuit (31; 302) having one end thereof connected to the testing port (103) and second port (101, 104) of the microcomputer (10) and having the other end thereof connected to one of the terminals (4a-4h, 5a-5e; 501, 502), and
the common output circuit (31; 302) functions as a communication interface with a tester (6) to output a test response signal corresponding to an output signal from the testing port (103) when the tester (6) is connected with the other end thereof while functioning as a driving circuit for driving a specified load device (7) to output a drive signal corresponding to an output signal from the other port when the load device (7) is connected with the other end thereof.

2. The electronic unit of claim 1, wherein the communication circuit (11) is a universal asynchronous receiver transceiver.

3. The electronic unit of claim 2, wherein the electronic unit (1) is a vehicle-mounted electronic unit to be mounted in a vehicle and to conduct no information communication with another electronic unit mounted in the vehicle.

4. The electronic unit of claim 3, wherein in a testing mode of the common output circuit (31; 302) the second port (101, 104) is a high impedance input port so as not to hinder communication output from the testing port (103).

5. The electronic unit of claim 1, wherein changes in the port settings are made, when a control signal indicating the start of a testing mode is fed from the tester (6) to the microcomputer (10).

6. The electronic unit of claim 1, wherein the tester (6) includes a communication interface (61) for communication between the microcomputer (10) and the tester (6).

7. The electronic unit of claim 6, wherein the communication interface (61) is a serial communication interface (61).

8. The electronic unit of claim 1, wherein the electronic unit (1) is a vehicle-mounted electronic unit to be mounted in a vehicle and to conduct no information communication with another electronic unit mounted in the vehicle.

9. The electronic unit of claim 1, wherein in a testing mode of the common output circuit (31; 302) the second port (101, 104) is a high impedance input port so as not to hinder communication output from the testing port (103).
